(19) United States
(12) Patent Application Publication
(10) Pub. No.: US 2026/0198189 A1
(43) Pub. Date: Jul. 9, 2026

(54) DISPLAY DEVICE AND ELECTRONIC DEVICE INCLUDING THE SAME

(71) Applicant: Samsung Display Co., LTD., Yongin-si (KR)

(72) Inventors: Dongjin YOON, Yongin-si (KR); DONGJIN PARK, Yongin-si (KR); DONGWOO SEO, Yongin-si (KR)

(21) Appl. No.: 19/440,231

(22) Filed: Jan. 5, 2026

(30) Foreign Application Priority Data
Jan. 6, 2025 (KR) 10-2025-0001341

(51) Int. Cl. H10K 59/124; H10K 102/00

(52) U.S. Cl. CPC H10K 59/124; H10K 2102/311

(57) ABSTRACT

A display device includes a display panel including a first non-folding area, a second non-folding area, a third non-folding area, a first folding area between the first non-folding area and the second non-folding area, and a second folding area between the second non-folding area and the third non-folding area, a bottom plate under the display panel and overlapping the first non-folding area, the first folding area, and the second non-folding area, and a protective layer on the display panel, in which the protective layer includes a first protective layer overlapping the first non-folding area, the first folding area, and the second non-folding area, and a second protective layer overlapping the second folding area and the third non-folding area.

This application claims priority to Korean Patent Application No. 10-2025-0001341, filed on Jan. 6, 2025, and all the benefits accruing therefrom under 35 U.S.C. § 119, the content of which in its entirety is herein incorporated by reference.

### BACKGROUND

### 1. Field

The disclosure relates to a display device and an electronic device including the display device.

### 2. Description of the Related Art

Recently, various types of lightweight and compact flat panel display devices have been developed. Flat panel display devices include liquid crystal displays (LCDs), field emission displays (FEDs), plasma display panels (PDPs), and organic light-emitting displays (OLEDs).

Among the flat panel display devices, the OLEDs display images using organic light-emitting diodes, which emit light through recoupling of electrons and holes. The OLEDs are receiving attention as next-generation displays because the OLEDs may have fast response speeds and operate with low power consumption.

### SUMMARY

The disclosure provides a display device having improved stability by preventing buckling in folding of the display device, and an electronic device including the display device.

The problem that the disclosure aims to solve is not limited to the problems mentioned above, and other problems and advantages of the disclosure that are not mentioned can be understood through the following description and may be understood more clearly by the examples of the disclosure. In addition, it will be appreciated that the problems and advantages to be solved by the disclosure may be realized by means and combinations thereof indicated in the claims.

According to an embodiment of the disclosure, a display device includes a display panel including a first non-folding area, a second non-folding area, a third non-folding area, a first folding area between the first non-folding area and the second non-folding area, and a second folding area between the second non-folding area and the third non-folding area, a bottom plate under the display panel and overlapping the first non-folding area, the first folding area, and the second non-folding area, and a protective layer on the display panel, in which the protective layer includes a first protective layer overlapping the first non-folding area, the first folding area, and the second non-folding area, and a second protective layer overlapping the second folding area and the third non-folding area.

In an embodiment, the first protective layer and the second protective layer may include different materials from each other.

In an embodiment, a first radius of curvature in folding of the first folding area may be greater than a second radius of curvature in folding of the second folding area.

In an embodiment, a ratio of the first radius of curvature to the second radius of curvature may be in a range of about 3.25 to about 12.5.

In an embodiment, the display device may further include an adhesive layer between the display panel and the protective layer in an area overlapping the first non-folding area, the first folding area, the second non-folding area, and the third non-folding area.

In an embodiment, the display device may further include a cover layer covering the display panel in an area overlapping the second folding area.

In an embodiment, a thickness of the adhesive layer may be greater than a thickness of the cover layer.

In an embodiment, in the second folding area, the first protective layer and the second protective layer may be spaced apart from each other.

In an embodiment, the display device may further include a window protective layer covering the protective layer.

In an embodiment, a thickness of the second protective layer may be greater than a thickness of the first protective layer.

According to another embodiment of the disclosure, a display device includes a display panel including a first non-folding area, a second non-folding area, a third non-folding area, a first folding area between the first non-folding area and the second non-folding area, and a second folding area between the second non-folding area and the third non-folding area, a protective layer including a first protective layer overlapping the first non-folding area, the first folding area, and the second non-folding area, and a second protective layer overlapping the second folding area and the third non-folding area, a window protective layer covering the first protective layer, and a cover layer covering the display panel in an area overlapping the second folding area, in which the first protective layer and the second protective layer include different materials from each other.

In an embodiment, the window protective layer may extend from the second non-folding area to the third non-folding area to cover the second protective layer.

In an embodiment, a first radius of curvature in folding of the first folding area may be greater than a second radius of curvature in folding of the second folding area.

In an embodiment, the second radius of curvature may be in a range of about 0.2 millimeter (mm) to about 0.4 mm.

In an embodiment, the display device may further include a bottom plate supporting the display panel and overlapping the first non-folding area, the first folding area, and the second non-folding area.

In an embodiment, the display device may further include an adhesive layer between the display panel and the protective layer in an area overlapping the first non-folding area, the first folding area, the second non-folding area, and the third non-folding area.

In an embodiment, a thickness of the adhesive layer may be greater than a thickness of the cover layer.

In an embodiment, in the second folding area, the first protective layer and the second protective layer may be spaced apart from each other.

In an embodiment, the display device may further include a fourth non-folding area and a third folding area between the first non-folding area and the fourth non-folding area.

In an embodiment, the first radius of curvature may be greater than a third radius of curvature in folding of the third folding area.

According to another aspect of the disclosure, an electronic device includes a memory which stores at least one program, a processor which operates by executing the at least one program, a display device which receives data from the processor and provides visual information, and a power module which supplies power to the display device, in which the display device includes a display panel including a first non-folding area, a second non-folding area, a third non-folding area, a first folding area between the first non-folding area and the second non-folding area, and a second folding area between the second non-folding area and the third non-folding area, a bottom plate under the display panel to overlap the first non-folding area, the first folding area, and the second non-folding area, and a protective layer on the display panel, in which the protective layer includes a first protective layer overlapping the first non-folding area, the first folding area, and the second non-folding area, and a second protective layer overlapping the second folding area and the third non-folding area.

In an embodiment, the electronic device may further include a frame which accommodates the display device, in which the frame may overlap the second folding area and include a rib covering the display panel.

In an embodiment, the electronic device may further include a cover layer between the rib and the display panel.

### BRIEF DESCRIPTION OF THE DRAWINGS

The above and other features of embodiments of the invention will become more apparent by describing in further detail embodiments thereof with reference to the accompanying drawings, in which:

FIG. 1 is a plan view schematically showing an example of a display device according to an embodiment of the disclosure;

FIG. 2 is a perspective view schematically showing a folding shape of the display device of FIG. 1;

FIG. 3 is a cross-sectional view schematically showing the folding shape of the display device of FIG. 1;

FIG. 4 is a block diagram schematically showing a structure of the display device of FIG. 1;

FIG. 5 is a schematic diagram of an equivalent circuit of a sub-pixel of the display device of FIG. 1;

FIG. 6 is a cross-sectional view schematically showing an example of a cross-section taken along line A-A′ of FIG. 1;

FIG. 7 is a cross-sectional view schematically showing an example of a cross-section taken along line B-B′ of FIG. 1;

FIG. 8 is an enlarged plan view of a region C of FIG. 7;

FIG. 9 is a cross-sectional view schematically showing another example of a cross-section taken along line B-B′ of FIG. 1;

FIG. 10 is a cross-sectional view schematically showing an example of a folding shape of a display device according to another embodiment of the disclosure;

FIG. 11 is a block diagram of an electronic device according to an embodiment; and

FIG. 12 show schematic diagrams of an electronic device according to various embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when an element is referred to as being “on” another element, it can be directly on the other element or intervening elements may be present therebetween. In contrast, when an element is referred to as being “directly on” another element, there are no intervening elements present.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

In the drawings, the size of components may be exaggerated or reduced for convenience of description. For example, as the size and thickness of each component shown in the drawings are arbitrarily shown for convenience of description, the disclosure is not necessarily limited to the illustration.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings, and in description with reference to the drawings, the same or corresponding components are given the same reference numerals.

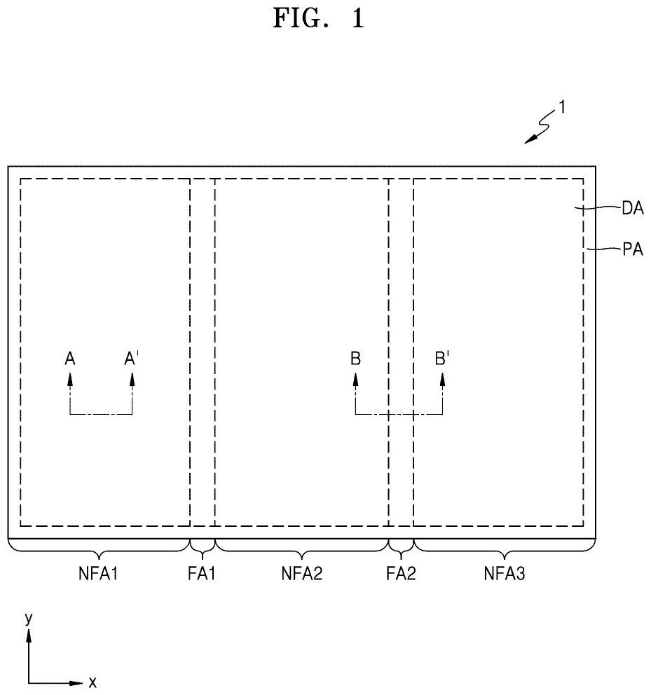

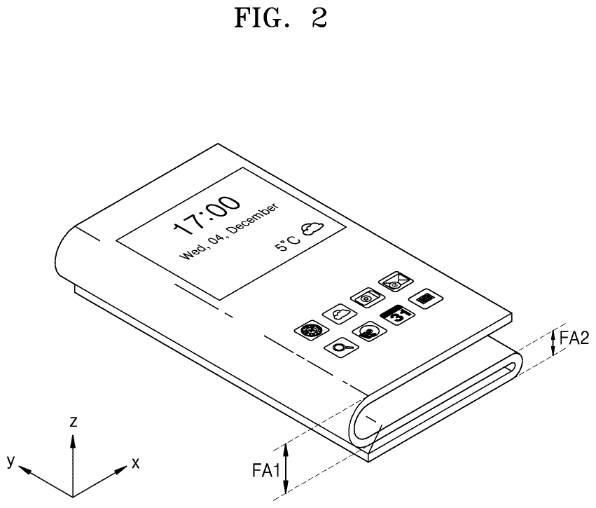

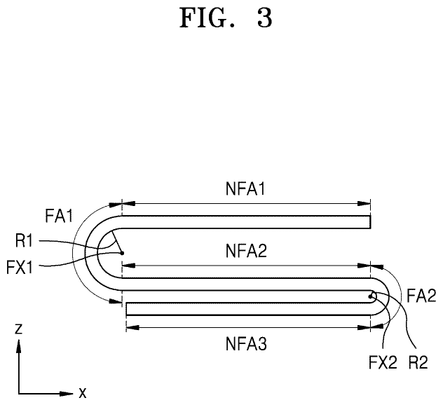

FIG. 1 is a plan view schematically showing an example of a display device according to an embodiment of the disclosure, FIG. 2 is a perspective view schematically showing a folding shape of the display device of FIG. 1, and FIG. 3 is a cross-sectional view schematically showing the folding shape of the display device of FIG. 1.

Herein, a ‘first direction x’ may be a longitudinal direction of a display device 1. A ‘second direction y’ may be a direction parallel to a width direction of the display device 1 or a folding axis of the display device 1. A ‘third direction z’ may be interpreted as a direction parallel to a stacking direction of components of the display device 1 (or a thickness direction of the display device 1) or perpendicular to both the first direction x and the second direction y, and the first direction x, the second direction y, and the third direction z may be directions perpendicular to one another.

The display device 1 may be a device that displays moving images or still images, and may provide a screen on a display panel or input or output data. The display device 1 may be used as a display screen for various electronic devices 1000 such as not only portable electronic devices including a mobile phone, a smart phone, a tablet personal computer (PC), a mobile communication terminal, an electronic notebook, an electronic book, a portable multimedia player (PMP), a navigation device, an ultra-mobile PC (UMPC), etc., but also a television, a laptop, a monitor, a billboard, an Internet of Things (IOT) device, etc.

The display device 1 according to an embodiment may be used in the electronic device 1000 such as a wearable device like a smart watch, a watch phone, a glasses-type display, and a head mounted display (HMD).

The display device 1 according to an embodiment may be used as a display of various electronic devices, for example, a dashboard of a vehicle, a center information display (CID) arranged on a center fascia or dashboard of a vehicle, a room mirror display replacing a side mirror of a vehicle, and a display arranged on the back of a front seat as entertainment for a rear seat of a vehicle.

Referring to FIGS. 1 to 3, the display device 1 according to an embodiment of the disclosure may include a display surface defined by the first direction x and the second direction y intersecting the first direction x. The display surface may include a display area DA in which a plurality of pixels are positioned, and a peripheral area PA positioned outside the display area DA.

The display area DA may display images. However, a region of the display area DA of FIG. 1 that overlaps a second folding area FA2 described below may not display an image. The peripheral area PA may not display an image. The peripheral area PA may surround the display area DA. However, without being limited to the foregoing example, the shape of the display area DA and the shape of the peripheral area PA may be variously modified.

The display device 1 may include a display panel including a first non-folding area NFA1, a second non-folding area NFA2, a third non-folding area NFA3, a first folding area FA1 between the first non-folding area NFA1 and the second non-folding area NFA2, and a second folding area FA2 between the second non-folding area NFA2 and the third non-folding area NFA3.

The display device 1 in a first mode may be defined as being in an unfolded state as shown in FIG. 1, and the display device 1 in a second mode may be defined as being in a folded state as shown in FIG. 2. As the display device 1 changes from the first mode to the second mode, the shapes of the first folding area FA1 and the second folding area FA2 change, but the shapes of the first non-folding area NFA1, the second non-folding area NFA2, and the third non-folding area NFA3 may not change.

As shown in FIGS. 2 and 3, the first folding area FA1 may be folded with respect to a first folding axis FX1 parallel to the second direction y. The first non-folding area NFA1 and the second non-folding area NFA2 may face each other, and the display device 1 may be inner-folded such that the display surface corresponding to the first non-folding area NFA1 and the second non-folding area NFA2 is not exposed to outside.

The first non-folding area NFA1, the second non-folding area NFA2, and the first folding area FA1 that are inner-folded may include a main display on which a main screen (e.g., a screen for displaying main contents such as an app, a moving image, a game, etc.) of the display device 1 is provided.

The first folding area FA1 may have a first radius of curvature R1 in folding. In an embodiment, for example, the first radius of curvature R1 in folding of the first folding area FA1 may be in a range of about 1.3 millimeter (mm) to about 2.5 mm.

The second folding area FA2 may be folded with respect to a second folding axis FX2 parallel to the second direction y. The second non-folding area NFA2 and the third non-folding area NFA3 may face each other, and the display device 1 may be out-folded such that the display surface corresponding to the second non-folding area NFA2 and the third non-folding area NFA3 is exposed to outside.

The third non-folding area NFA3 that is out-folded may include a sub-display on which an auxiliary screen (e.g., a screen displaying specific notifications, state information, additional functions, etc.) supporting the main display of the display device 1 is provided. As a rib of a frame that accommodates the display device 1 described below is arranged in the second folding area FA2 that is out-folded, the screen of the display device 1 may not be driven in the second folding area FA2.

The second folding area FA2 may have a second radius of curvature R2 in folding. In an embodiment, for example, the second radius of curvature R2 in folding of the second folding area FA2 may be in a range of about 0.2 mm to about 0.4 mm. A ratio of the first radius of curvature R1 to the second radius of curvature R2 may be in a range of about 3.25 to about 12.5.

Conventionally, as the second radius of curvature R2 in folding of the second folding area is greater than the second radius of curvature R2 of the display device 1, due to slip in different directions in double folding (in both inner-folding and out-folding as shown in FIG. 2), stress may be concentrated on the second folding area FA2 such that buckling such as bending or wrinkling of the second folding area FA2 occurs, thereby degrading stability of the display device 1.

As described herein, the display device 1 according to embodiments of the disclosure may not include a bottom plate under the display panel in the second folding area FA2 and the third non-folding area NFA3 to reduce the second radius of curvature R2 in the second folding area FA2, and may not include a protective layer and an adhesive layer in the second folding area FA2, thereby effectively preventing buckling in folding of the display device 1 and thus improving the stability of the display device 1 and the electronic device including the same.

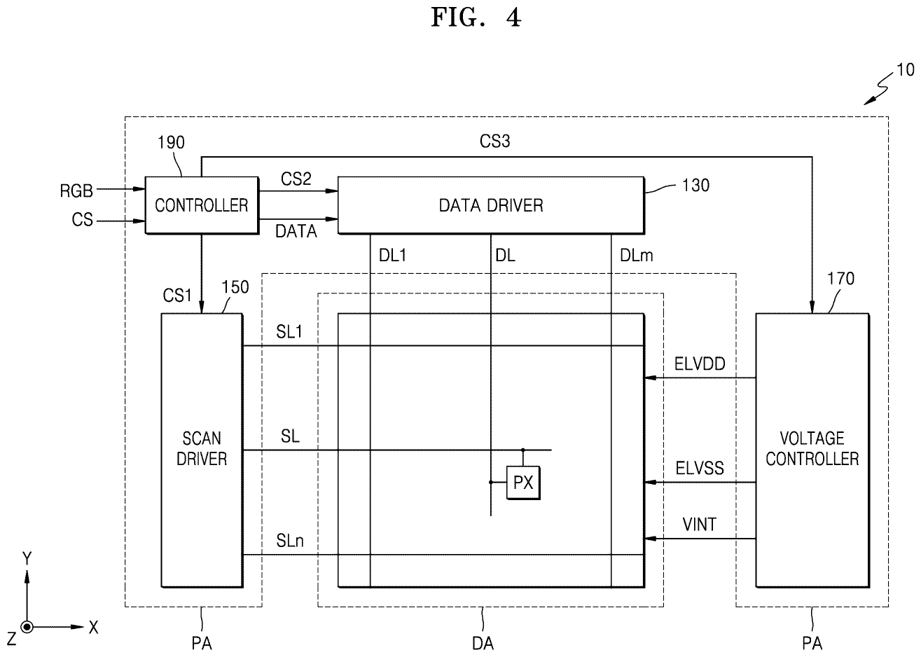

FIG. 4 is a block diagram schematically showing a structure of the display device of FIG. 1.

Referring to FIG. 4, in an embodiment of the display device, a plurality of scan lines SL1 to SLn extending in the first direction x, a plurality of data lines DL1 to DLm extending in the second direction y perpendicular to the first direction x, and a plurality of sub-pixels PX may be positioned in the display area DA. Here, each of m and n is a natural number greater than 1.

Lines for applying electrical signals to the plurality of sub-pixels PX may include the plurality of scan lines SL1 to SLn, the plurality of data lines DL1 to DLm, etc. The plurality of scan lines SL1 to SLn may be arranged in a plurality of rows extending, for example, in the first direction x, to transmit scan signals to sub-pixels PX, the plurality of data lines DL1 to DLm may be arranged in a plurality of columns extending, for example, in the second direction y, to transmit data signals to the sub-pixels PX, and the plurality of sub-pixels PX may be positioned at intersections between the plurality of scan lines SL1 to SLn and the plurality of data lines DL1 to DLm.

Each sub-pixel PX may include a light-emitting element that emits red, green, blue, or white light. In an embodiment, for example, each sub-pixel PX may include, but not limited to, an organic light emitting diode as a light-emitting element.

In the peripheral area PA, a data driver 130 that provides data signals to the display area DA, a scan driver 150 that provides scan signals to the display area DA, a voltage controller 170 that controls voltages supplied to the display area DA, a controller 190 that may control the data driver 130, the scan driver 150, and the voltage controller 170, etc., may be arranged.

The voltage controller 170 may generate and control a first voltage ELVDD, a second voltage ELVSS, and an initialization voltage VINT, which are provided to the display area DA.

The first voltage ELVDD, the second voltage ELVSS, and the initialization voltage VINT may be applied to the plurality of sub-pixels PX. In an embodiment, for example, the first voltage ELVDD may be a positive voltage, and the second voltage ELVSS may be a negative voltage or ground voltage. In such an embodiment, the second voltage ELVSS may have a lower level than the first voltage ELVDD.

The controller 190 may receive image signals RGB and a control signal CS from an external device (e.g., a system board). The controller 190 may convert data formats of the image signals RGB to comply with specifications of an interface with the data driver 130 and generate image data DATA. The controller 190 may provide the image data DATA having the converted data format to the data driver 130.

The controller 190 may generate and output a first control signal CS1, a second control signal CS2 and a third control signal CS3 in response to the control signal CS provided from the external device. The first control signal CS1 may be defined as a scan control signal, the second control signal CS2 may be defined as a data control signal, the third control signal CS3 may be defined as a voltage control signal. The first control signal CS1 may be provided to the scan driver 150. The second control signal CS2 may be provided to the data driver 130. The third control signal CS3 may be provided to the voltage controller 170.

The scan driver 150 may generate a plurality of scan signals in response to the first control signal CS1. The plurality of scan signals may be applied to the plurality of sub-pixels PX via the plurality of scan lines SL1 to SLn.

The data driver 130 may generate a plurality of data voltages corresponding to the image data DATA in response to the second control signal CS2. The plurality of data voltages may be applied to the plurality of sub-pixels PX via the data lines DL1 to DLm. The data driver 130 may simultaneously provide the data voltages generated in units of sub-pixel rows to the plurality of sub-pixels PX to the data lines DL1 to DLm.

The plurality of sub-pixels PX may receive a plurality of data voltages in response to a plurality of scan signals. The plurality of sub-pixels PX may display an image by emitting light with a brightness corresponding to the plurality of data voltages. The plurality of sub-pixels PX may display the image by emitting light sequentially or simultaneously.

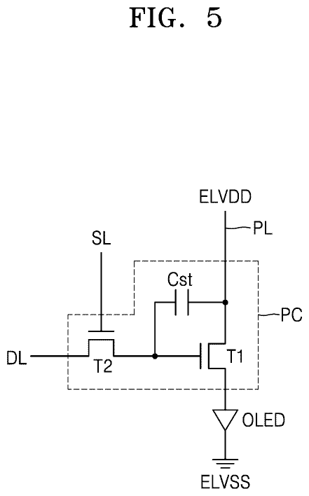

FIG. 5 is a schematic diagram of an equivalent circuit of a sub-pixel of the display device of FIG. 1.

Referring to FIG. 5, in an embodiment of a sub-pixel of the display device, a pixel circuit PC may be connected to a display element, for example, an organic light-emitting diode OLED. The pixel circuit PC may be arranged in the display area DA. The pixel circuit PC may include a driving thin film transistor T1, a switching thin film transistor T2, and a storage capacitor Cst. The organic light-emitting diode OLED may emit red, green, or blue light, or may emit red, green, blue, or white light.

The switching thin film transistor T2 may be connected to a scan line SL and a data line DL, and may transmit a data signal or data voltage input from the data line DL to the driving thin film transistor T1 based on a scan signal or switching voltage input from the scan line SL. The storage capacitor Cst may be connected to the switching thin film transistor T2 and a driving voltage line PL, and may store a voltage corresponding to a difference between a voltage received from the switching thin film transistor T2 and the first voltage ELVDD supplied to the driving voltage line PL.

The driving thin film transistor T1 may be connected to the driving voltage line PL and the storage capacitor Cst, and may control a driving current flowing through the organic light-emitting diode OLED from the driving voltage line PL in response to a voltage value stored in the storage capacitor Cst. The organic light-emitting diode OLED may emit light with a certain brightness corresponding to the driving current. A counter electrode of the organic light-emitting diode OLED may receive the second voltage ELVSS.

Although FIG. 5 shows an embodiment where the pixel circuit PC includes two thin film transistors and one storage capacitor, the pixel circuit PC may include three, four, five or more thin film transistors, and the pixel circuit PC may include two, three or more capacitors in another embodiment.

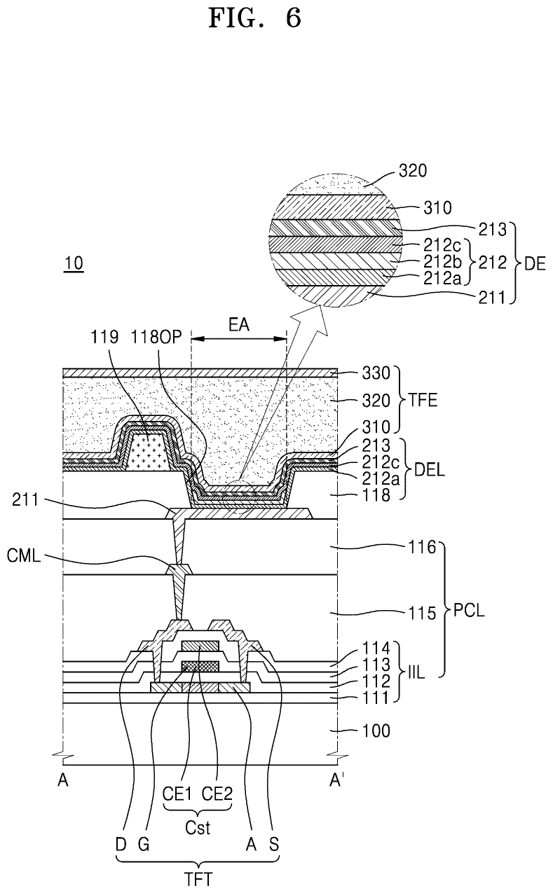

FIG. 6 is a cross-sectional view schematically showing an example of a cross-section taken along line A-A′ of FIG. 1.

Referring to FIG. 6, an embodiment of the display device 1 may include a display panel 10. In an embodiment, the display panel 10 may include a substrate 100, a buffer layer 111, a pixel circuit layer PCL, a display element layer DEL, and a thin film encapsulation layer TFE.

The substrate 100 may include or be formed of a transparent glass material having SiO₂ as a main component. However, the disclosure is not limited thereto, and the substrate 100 may also include or be formed of a transparent plastic material or polymer resin. The plastic material or polymer resin may include at least one selected from polyethersulfone (PES), polyacrylate (PAR), polyetherimide (PEI), polyethylene naphthalate (PEN), polyethyleneterephthalate (PET), polyphenylene sulfide (PPS), polyarylate, polyimide, polycarbonate (PC), cellulose triacetate (TAC), and cellulose acetate propionate (CAP), for example. In an embodiment, the substrate 100 may have a multilayer structure including a base layer including the plastic material or polymer resin described above and a barrier layer (not shown). The substrate 100 including the polymer resin may have flexible, rollable, and bendable properties.

The buffer layer 111 may be arranged on the substrate 100. The buffer layer 111 may include an inorganic insulating material such as silicon nitride, silicon oxynitride, and silicon oxide, and may be a single layer or multilayer including the inorganic insulating material.

The pixel circuit layer PCL may be arranged on the buffer layer 111. The pixel circuit layer PCL may include an inorganic insulating layer IIL, a first planarization layer 115, and a second planarization layer 116, arranged on or/and under a thin film transistor TFT and components thereof. The inorganic insulating layer IIL may include a first gate insulating layer 112, a second gate insulating layer 113, and an interlayer insulating layer 114.

The thin film transistor TFT may include a semiconductor layer A that may include polysilicon. The semiconductor layer A may include at least one selected from amorphous silicon, an oxide semiconductor, an organic semiconductor, for example. The semiconductor layer A may include a channel region and a drain region and a source region respectively arranged on opposite sides of the channel region. A gate electrode G may overlap the channel region.

The gate electrode G may include a low-resistance metal material. The gate electrode G may include a conductive material including at least one selected from molybdenum (Mo), aluminum (Al), copper (Cu) and titanium (Ti), for example, and may be formed as a multilayer or single layer including such a conductive material.

The first gate insulating layer 112 between the semiconductor layer A and the gate electrode G may include an inorganic insulating material such as a silicon oxide (SiO₂), a silicon nitride (SiNX), a silicon oxynitride (SiON), an aluminum oxide (Al₂O₃), a titanium oxide (TiO₂), a tantalum oxide (Ta₂O₅), a hafnium oxide (HfO₂) and a zinc oxide (ZnOX), for example. The zinc oxide (ZnOX) may be a zinc oxide (ZnO) and/or a zinc peroxide (ZnO₂).

The second gate insulating layer 113 may be provided to cover the gate electrode G. Like the first gate insulating layer 112, the second gate insulating layer 113 may include an inorganic insulating material such as a silicon oxide (SiO₂), a silicon nitride (SiNX), a silicon oxynitride (SiON), an aluminum oxide (Al₂O₃), a titanium oxide (TiO₂), a tantalum oxide (Ta₂O₅), a hafnium oxide (HfO₂) and a zinc oxide (ZnOX), for example. The zinc oxide (ZnOX) may be a zinc oxide (ZnO) and/or a zinc peroxide (ZnO₂).

An upper electrode CE2 of the storage capacitor Cst may be arranged above the second gate insulating layer 113. The upper electrode CE2 may overlap the gate electrode G thereunder in a vertical direction (i.e., a thickness direction of the substrate 100). The gate electrode G and the upper electrode CE2 overlapping each other with the second gate insulating layer 113 therebetween may form the storage capacitor Cst of the pixel circuit. The gate electrode G may function as a lower electrode CE1 of the storage capacitor Cst. In this way, the storage capacitor Cst and the thin film transistor TFT may be formed to overlap each other in the vertical direction. However, the disclosure is not limited thereto, and in some embodiments, the storage capacitor Cst may be formed not to overlap the thin film transistor TFT in the vertical direction.

The upper electrode CE2 may include at least one selected from aluminum (Al), platinum PT, palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or multiple layers of at least one selected from the materials listed above.

The interlayer insulating layer 114 may cover the upper electrode CE2. The interlayer insulating layer 114 may include at least one selected from a silicon oxide (SiO₂), a silicon nitride (SiNX), a silicon oxynitride (SiON), an aluminum oxide (Al₂O₃), a titanium oxide (TiO₂), a tantalum oxide (Ta₂O₅), a hafnium oxide (HfO₂) and a zinc oxide (ZnOX), for example. The zinc oxide (ZnOX) may be a zinc oxide (ZnO) and/or a zinc peroxide (ZnO2). The interlayer insulating layer 114 may be a single layer or multiple layers including the inorganic insulating material listed above.

Each of the drain electrode D and the source electrode S may be positioned on the interlayer insulating layer 114. The drain electrode D and source electrode S may include a material having good conductivity. The drain electrode D and the source electrode S may include a conductive material including at least one selected from molybdenum (Mo), aluminum (Al), copper (Cu), and titanium (Ti), for example., and may be formed as multiple layers or a single layer including the conductive material. In an embodiment, the drain electrode D and the source electrode S may have a multilayer structure of Ti/Al/Ti.

The first planarization layer 115 may be arranged to cover the drain electrode D and the source electrode S. The first planarization layer 115 may include an organic insulating layer. The first planarization layer 115 may include an organic insulator including at least one selected from a general-purpose polymer such as polymethylmethacrylate (PMMA) or polystyrene (PS), a polymer derivative having a phenol-based group, an acrylic polymer, an imide polymer, an aryl ether polymer, an amide polymer, a fluorinated polymer, a p-xylene polymer, a vinyl alcohol polymer, and a blend thereof.

A connection electrode CML may be arranged above the first planarization layer 115. In such an embodiment, the connection electrode CML may be connected to the drain electrode D or the source electrode S via a contact hole of the first planarization layer 115. The connection electrode CML may include a material with high conductivity. The connection electrode CML may include a conductive material including at least one selected from molybdenum (Mo), aluminum (Al), copper (Cu) and titanium (Ti), for example, and may be formed as multiple layers or a single layer including the conductive material. In an embodiment, the connection electrode CML may have a multilayer structure of Ti/Al/Ti.

The second planarization layer 116 may be arranged to cover the connection electrode CML. The second planarization layer 116 may include an organic insulating layer. The second planarization layer 116 may include an organic insulator including at least one selected from a general-purpose polymer such as polymethylmethacrylate (PMMA) or polystyrene (PS), a polymer derivative having a phenol-based group, an acrylic polymer, an imide polymer, an aryl ether polymer, an amide polymer, a fluorinated polymer, a p-xylene polymer, a vinyl alcohol polymer, and a blend thereof.

The display element layer DEL may be arranged on the pixel circuit layer PCL. The display element layer DEL may include a display element DE. The display element DE may be an organic light-emitting diode. A pixel electrode 211 of the display element DE may be electrically connected to the connection electrode CML through a contact hole of the second planarization layer 116.

The pixel electrode 211 may include a conductive oxide such as an indium tin oxide (ITO), an indium zinc oxide (IZO), a zinc oxide (ZnO), an indium oxide (In₂O₃), an indium gallium oxide (IGO), or an aluminum zinc oxide (AZO). In another embodiment, the pixel electrode 211 may include a reflective film including silver (Ag), magnesium (Mg), aluminum (Al), platinum PT, palladium (Pd), gold (Au), nickel (Ni), neodymium (Nd), iridium (Ir), chromium (Cr), or a compound thereof. In another embodiment, the pixel electrode 211 may further include a film including or formed of ITO, IZO, ZnO or In₂O₃ above/below the reflective film.

A pixel-defining film 118 defining an opening 118OP exposing a central portion of the pixel electrode 211 may be arranged on the pixel electrode 211. The pixel-defining film 118 may include an organic insulating material and/or an inorganic insulating material. The opening 118OP may define an emission area EA of light emitted from the display element DE (hereinafter referred to as an emission area). A width of the opening 118OP may correspond to a width of the emission area EA of the display element DE.

In an embodiment, the pixel-defining film 118 may include a light-blocking material and may be provided in black. The light-blocking material may include at least one selected from a resin or paste containing carbon black, carbon nanotubes, and black dye, metal particles such as nickel, aluminum, molybdenum and alloys thereof, metal oxide particles (e.g., a chromium oxide) and metal nitride particles (e.g., a chromium nitride), for example. In an embodiment where the pixel-defining film 118 includes a light-blocking material, external light reflection by metal structures arranged under the pixel-defining film 118 may be reduced.

A spacer 119 may be arranged on the pixel-defining film 118. The spacer 119 may be used to prevent damage to the substrate 100 in a manufacturing method for manufacturing a display device. A mask sheet may be used in manufacturing of the display panel 10, and in this case, when the mask sheet enters the opening 118OP of the pixel-defining film 118 or is in close contact with the pixel-defining film 118 to deposit a deposition material on the substrate 100, a defect that may occur when a part of the substrate 100 is damaged or broken by the mask sheet may be effectively prevented.

The spacer 119 may include an organic insulating material such as polyimide. The spacer 119 may include an inorganic insulator such as a silicon nitride or a silicon oxide, or may include an organic insulator and an inorganic insulator.

In an embodiment, the spacer 119 may include a material that is different from that of the pixel-defining film 118. In another embodiment, the spacer 119 may include a same material as the pixel-defining film 118, and the pixel-defining film 118 and the spacer 119 may be formed together in a mask process using a halftone mask or the like.

An intermediate layer 212 may be arranged on the pixel-defining film 118. The intermediate layer 212 may include a light-emitting layer 212b arranged in the opening 118OP of the pixel-defining film 118. The light-emitting layer 212b may include a polymer or low-molecular organic material that emits light of a selected color.

A first functional layer 212a and a second functional layer 212c may be arranged below and above the light-emitting layer 212b, respectively. The first functional layer 212a may include, for example, a hole transport layer (HTL) or both an HTL and a hole injection layer (HIL). The second functional layer 212c is a component positioned on the light-emitting layer 212b and may be optional. The second functional layer 212c may include an electron transport layer (ETL) and/or an electron injection layer (EIL). The first functional layer 212a and/or the second functional layer 212c may be a common layer formed to cover the entire substrate 1000 like a counter electrode 213 described below.

The counter electrode 213 may include a conductive material with a low work function. In an embodiment, for example, the counter electrode 213 may include a (semi)transparent layer including silver (Ag), magnesium (Mg), aluminum (Al), platinum PT, palladium (Pd), gold (Au), nickel (Ni), neodymium (Nd), iridium (Ir), chromium (Cr), lithium (Li), calcium (Ca), or an alloy thereof. The counter electrode 213 may further include a layer such as ITO, IZO, ZnO or In₂O₃ on the (semi)transparent layer including at least one selected from the materials listed above.

In some embodiments, a capping layer (not shown) may be further arranged on the counter electrode 213. The capping layer may include LiF, an inorganic material, and/or an organic material.

The thin film encapsulation layer TFE may be arranged on the counter electrode 213. In an embodiment, the thin film encapsulation layer TFE may include at least one inorganic encapsulation layer and at least one organic encapsulation layer. In an embodiment, for example, the thin film encapsulation layer TFE may include a first inorganic encapsulation layer 310, an organic encapsulation layer 320, and a second inorganic encapsulation layer 330 that are sequentially stacked.

The first inorganic encapsulation layer 310 and the second inorganic encapsulation layer 330 may include at least one inorganic materials selected form an aluminum oxide, a titanium oxide, a tantalum oxide, a hafnium oxide, a zinc oxide, a silicon oxide, a silicon nitride, and a silicon oxynitride. The organic encapsulation layer 320 may include a polymer-based material. The polymer-based material may include at least one selected from an acrylic resin, an epoxy resin, polyimide and polyethylene, for example. In an embodiment, the organic encapsulation layer 320 may include acrylate.

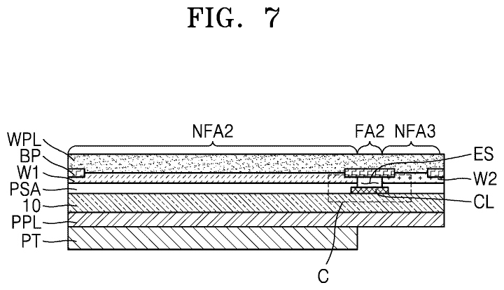

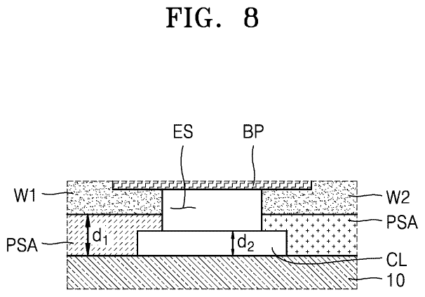

FIG. 7 is a cross-sectional view schematically showing an example of a cross-section taken along line B-B′ of FIG. 1, and FIG. 8 is an enlarged plan view of a region C of FIG. 7.

Referring to FIGS. 7 and 8 together with FIG. 1, the display device 1 according to an embodiment of the disclosure may include the display panel 10 including the first non-folding area NFA1, the second non-folding area NFA2, the third non-folding area NFA3, the first folding area FA1 between the first non-folding area NFA1 and the second non-folding area NFA2, and the second folding area FA2 between the second non-folding area NFA2 and the third non-folding area NFA3, a bottom plate PT supporting the display panel 10 and overlapping the first non-folding area NFA1, the first folding area FA1, and the second non-folding area NFA2, and protective layers W1 and W2 protecting the display panel 10.

The display device 1 may not include the bottom plate PT under the display panel 10 in the second folding area FA2 and the third non-folding area NFA3, and may not include an adhesive layer PSA and the protective layers W1 and W2 positioned above the display panel 10 in the second folding area FA2. That is, the bottom plate PT under the display panel 10 may not overlap the second folding area FA2 and the third non-folding area NFA3, and the adhesive layer PSA and the protective layers W1 and W2 positioned above the display panel 10 may not overlap the second folding area FA2 in a thickness direction of the display panel 10 (or the third direction z in FIG. 2).

In some embodiments, the display device 1 according to an embodiment of the disclosure may include a lower member, the display panel 10, and a window that are sequentially stacked in the thickness direction of the display panel 10 or the third direction (z in FIG. 2). The lower member may refer to a configuration arranged under the display panel 10.

The window may include the protective layers W1 and W2, the window protective layer WPL on the protective layers W1 and W2, and a bezel pattern BP on a bottom surface of the window protective layer WPL.

In an embodiment, the window protective layer WPL may absorb an external impact applied to a front surface of the display panel 10. The window protective layer WPL may include, for example, a synthetic resin film. The synthetic resin film of the window protective layer WPL may include at least one selected form polyimide, polycarbonate, polyamide, triacetylcellulose, polymethylmethacrylate, or polyethylene terephthalate. A thickness of the window protective layer WPL may be, for example, in a range of about 50 micrometers (μm) to about 80 μm.

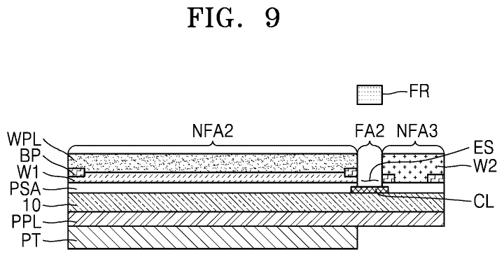

As described later, the window protective layer WPL may be arranged on the first protective layer W1 and the second protective layer W2 to cover the first protective layer W1, the second protective layer, and an empty space ES may be defined between the first protective layer W1 and the second protective layer W2. The window protective layer WPL may cover the top surface of the first protective layer W1 and may not be arranged on the second protective layer W2, as described later in FIG. 9.

In another embodiment, a functional layer (not shown) may be further arranged on the window protective layer WPL. The functional layer may include at least one selected from a hard coating layer, an anti-fingerprint layer, and an anti-reflection layer.

The bezel pattern BP may be arranged on a surface of the protective layers W1 and W2 or a surface of the window protective layer WPL. FIGS. 7 and 8 show an embodiment where the bezel pattern BP is positioned on a bottom surface of the window protective layer WPL, but the disclosure is not limited thereto, and the bezel pattern BP may be positioned on the top surface of the window protective layer WPL in another embodiment. The bezel pattern BP may be, for example, a colored light-blocking film.

The bezel pattern BP may be formed, for example, using a coating method. The bezel pattern BP may include a base material and a dye or pigment mixed into the base material. The peripheral area PA shown in FIG. 1 may be defined by the shape of the bezel pattern BP.

The protective layers W1 and W2 may be positioned below the window protective layer WPL. The protective layers W1 and W2 may be chemically tempered glass. In an embodiment, for example, the protective layers W1 and W2 may be ultra-thin glass or hybrid thin glass. The protective layers W1 and W2 may provide mechanical strength and flexibility to the display device 1, thereby minimizing the occurrence of wrinkles in the display device 1 even when the display device 1 is repeatedly folded and unfolded. As described later, the first protective layer W1 and the second protective layer W2 of the protective layers W1 and W2 may include different materials from each other.

The protective layers W1 and W2 may include the first protective layer W1 overlapping the first non-folding area NFA1, the first folding area FA1, and the second non-folding area NFA2, and the second protective layer W2 overlapping the third non-folding area NFA3. The protective layers W1 and W2 may not be arranged on the display panel 10 in the second folding area FA2 or may be arranged not to overlap the second folding area FA1.

In an embodiment, for example, as described above, the first non-folding area NFA1, the second non-folding area NFA2, and the first folding area FA1 that are inner-folded may include the main display on which the main screen is displayed, such that the first protective layer W1 of the main display may include a material that has high flexibility to withstand repeated folding and high transparency to avoid damage to a high-resolution screen of the display panel 10.

The third non-folding area NFA3 that is out-folded may include the sub-display on which the auxiliary screen supporting the main display of the display device 1 is displayed, and the sub-display may be directly exposed to an external environment, such that the second protective layer W2 of the sub-display may include a material having high impact resistance and scratch resistance.

However, the disclosure is not limited thereto, and the first protective layer W1 and the second protective layer W2 that are spaced apart from each other may include a same material as each other.

In an embodiment, as the empty space ES may be defined or provided between the window protective layer WPL and a cover layer CL described below in the second folding area FA2, the bezel pattern BP may be provided at a position overlapping the second folding area FA2 on the bottom surface of the window protective layer WPL to block reflected light.

The window protective layer WPL may be arranged on the first protective layer W1. The window protective layer WPL arranged on the first protective layer W1 may extend from the second non-folding area NFA2 to the third non-folding area NFA3 to protect the second protective layer W2. The window protective layer WPL may be arranged to integrally cover the first protective layer W1, the second protective layer W2, and the empty space ES between the first protective layer W1 and the second protective layer W2.

Window protective layers of different materials may be arranged on the first protective layer W1 and the second protective layer W2.

The first protective layer W1 and the second protective layer W2 may be coupled to the display panel 10 through the adhesive layer PSA. The adhesive layer PSA may be a pressure sensitive adhesive (PSA) film or an optically clear adhesive (OCA) layer. In an embodiment, as described above, as the first protective layer W1 and the second protective layer W2 may include different materials from each other, the adhesive layer PSA under the first protective layer W1 and the second protective layer W2 may also include different materials, but the disclosure is not limited thereto, and the adhesive layer PSA under the first protective layer W1 and the second protective layer W2 may include a same material as each other in another embodiment.

The first protective layer W1 and the second protective layer W2 are spaced apart from each other in the second folding area FA2, such that the adhesive layers PSA arranged on the bottom surfaces of the first protective layer W1 and the second protective layer W2 in the second folding area FA2 may also be spaced apart from each other. As a result, the empty space ES may be defined or provided between the display panel 10 overlapping the second folding area FA2 and the window protective layer WPL. Thus, in folding of the second folding area FA2, the second radius of curvature R2 in FIG. 3 may be reduced, thereby effectively preventing buckling caused by stress concentration on the second folding area FA2 during folding.

The display panel 10 overlapping the second folding area FA2 may be vulnerable to moisture penetration or cracks due to the empty space ES. Thus, the cover layer CL covering the display panel 10 may be arranged on the display panel 10 to overlap the second folding area FA2.

The cover layer CL that effectively prevents moisture penetration or cracks of the display panel 10 may include a natural resin film or a synthetic resin film. The synthetic resin film may include at least one selected from polyimide, polycarbonate, polyamide, triacetylcellulose, polymethylmethacrylate, or polyethylene terephthalate.

The cover layer CL may absorb an external impact applied to the front surface of the display panel 10 together with the window protective layer WPL.

A thickness d1 of the adhesive layer PSA under the first protective layer W1 and the second protective layer W2 may be greater than a thickness d2 of the cover layer CL arranged in the second folding area FA2. As a result, the second radius of curvature R2 of the second folding area FA2 may be reduced, thereby effectively preventing buckling in the second folding area FA2.

in an embodiment as described above, in the second folding area FA2, the display device 1 and the electronic device including the display device 1 may include the cover layer CL having a less thickness than the adhesive layer PSA between the display panel 10 and the window protective layer WPL without including the protective layers W1 and W2 therebetween, thereby effectively preventing buckling caused by stress concentration on the second folding area FA2 during double folding and thus improving the stability of the display device 1 and the electronic device including the same.

In an embodiment, as shown in FIG. 7, the lower member may be arranged on the bottom of the display panel 10. The lower member may include a panel protection film PPL, the bottom plate PT, and a cushion layer (not shown).

The panel protection film PPL may be arranged under the display panel 10. Thus, the panel protection film PPL may protect the bottom of the display panel 10. The panel protection film PPL may include, for example, a flexible synthetic resin film.

The panel protection film PPL may include a base film and a shielding portion. The base film may include at least one selected from polyurethane and polyimide. The shielding portion may include magnetic metal powder (MMP). Thus, the panel protection film PPL according to an embodiment of the disclosure may have an electromagnetic shielding function. The shielding portion may be arranged on a top surface of the panel protection film PPL adjacent to the display panel 10, or the MMP may be arranged inside the panel protection film PPL.

The bottom plate PT may be arranged under the panel protection film PPL. In an embodiment, a barrier layer (not shown) may be arranged between the bottom plate PT and the panel protection film PPL. The barrier layer may increase resistance to compressive force due to external pressure. Thus, the barrier layer may effectively prevent deformation of the display panel 10.

The barrier layer may include a flexible plastic material such as polyimide, polycarbonate, polyamide, triacetylcellulose, polymethylmethacrylate, or polyethylene terephthalate.

In an embodiment, the barrier layer may include a colored film having a low light transmissivity. In such an embodiment, the barrier layer may absorb light incident from outside. In an embodiment, for example, the barrier layer may include a black synthetic resin film. As a result, when the display panel 10 is viewed from the top of the window protective layer WPL, components arranged on the bottom of the barrier layer may not be visible to a user.

The bottom plate PT may support the display panel 10. The bottom plate PT may include, for example, a material having an elastic modulus of about 60 gigapascals (GPa) or greater at a room temperature (e.g., a temperature in a range of about 20° C. and 22° C. or in a range of about 18° C. to about 24° C.). The bottom plate PT may include a single metal material or an alloy of a plurality of metal materials to improve the heat dissipation performance of the display device 1 and the electronic device including the display device 1. In an embodiment, for example, the bottom plate PT may be stainless steel, but may include various metal materials without being limited thereto. In an embodiment, a heat dissipation layer may be arranged under the bottom plate PT.

The bottom plate PT may be positioned under the display panel 10 in the first non-folding area NFA1, the first folding area FA1, and the second non-folding area NFA2, and may be omitted in the second folding area FA2 and the third non-folding area NFA3.

As a result, the second radius of curvature R2 of the second folding area FA2 may be reduced, thereby effectively preventing buckling caused by stress concentration on the second folding area FA2 during double folding and thus improving the stability of the display device 1 and the electronic device including the same.

The cushion layer may be arranged under the bottom plate PT. However, the disclosure is not limited thereto, and positions of the bottom plate PT and the cushion layer may be interchanged with each other.

The cushion layer may prevent the display panel 10 from being damaged. The cushion layer may protect the display panel 10 from impact transmitted from the bottom of the display panel 10. In an embodiment, for example, the cushion layer may include foam or a sponge. The foam may include polyurethane foam or thermoplastic polyurethane foam. In an embodiment where the cushion layer includes foam, a barrier film may be added as a base layer to the cushion layer, and a foaming agent may be foamed onto the barrier film to form the cushion layer.

FIG. 9 is a cross-sectional view schematically showing another example of a cross-section taken along line B-B′ of FIG. 1.

Referring to FIG. 9, the display device 1 according to another embodiment of the disclosure may include the display panel 10 including the first non-folding area NFA1, the second non-folding area NFA2, the third non-folding area NFA3, the first folding area FA1 between the first non-folding area NFA1 and the second non-folding area NFA2, and the second folding area FA2 between the second non-folding area NFA2 and the third non-folding area NFA3, a bottom plate PT supporting the display panel 10 and overlapping the first non-folding area NFA1, the first folding area FA1, and the second non-folding area NFA2, and the protective layers W1 and W2 protecting the display panel 10.

In some embodiments, the display device 1 may include a lower member, the display panel 10, and a window that are sequentially stacked a thickness direction of the display panel 10 (or in the third direction z of FIG. 2). The lower member may refer to a component arranged on the bottom of the display panel 10.

The window may include the protective layers W1 and W2, the window protective layer WPL on the protective layers W1 and W2, and the bezel pattern BP on the bottom surface of the window protective layer WPL.

The protective layers W1 and W2 may include the first protective layer W1 overlapping the first non-folding area NFA1, the first folding area FA1, and the second non-folding area NFA2, and the second protective layer W2 overlapping the third non-folding area NFA3. No protective layer may be arranged on the display panel 10 in the second folding area FA2.

The first protective layer W1 and the second protective layer W2 may include different materials from each other. In an embodiment, for example, as described above, the first non-folding area NFA1, the second non-folding area NFA2, and the first folding area FA1 that are inner-folded may include the main display on which the main screen is displayed, such that the first protective layer W1 of the main display may include a material that has high flexibility to withstand repeated folding and high transparency to avoid damage to a high-resolution screen of the display panel 10.

The third non-folding area NFA3 that is out-folded may include the sub-display on which the auxiliary screen supporting the main display of the display device 1 is displayed, and the sub-display may be directly exposed to an external environment, such that the second protective layer W2 of the sub-display may include a material having high impact resistance and scratch resistance.

However, the disclosure is not limited thereto, and the first protective layer W1 and the second protective layer W2 that are spaced apart from each other may include a same material as each other.

The window protective layer WPL covering the first protective layer W1 may be arranged on the first protective layer W1. The window protective layer WPL may not be arranged on the second protective layer W2. The window protective layer WPL may be arranged in the first non-folding area NFA1, the second non-folding area NFA2, and the first folding area FA1, and the window protective layer WPL may not be arranged in the second folding area FA2 and the third non-folding area NFA3.

In such an embodiment, as the window protective layer WPL is not arranged on the second protective layer W2, the thickness of the second protective layer W2 may be greater than the thickness of the first protective layer W1 to protect the display panel 10 under the second protective layer W2. In an embodiment, for example, the thickness of the first protective layer W1 may be in a range of about 30 μm to about 120 μm, and the thickness of the first protective layer W1 may be in a range of about 100 μm to about 200 μm. In such an embodiment where the thickness of the second protective layer W2 of the sub-display is greater than the thickness of the first protective layer W1 of the main display, the flexibility of the main display may be improved, and the durability of the sub-display may be improved.

The bezel pattern BP may be arranged between the first protective layer W1 and the window protective layer WPL in the first non-folding area NFA1, the second non-folding area NFA2, and the first folding area FA1, and the window protective layer WPL may not be arranged on the second protective layer W2 in the third non-folding area NFA3, such that the bezel pattern BP may be arranged on a bottom surface of the second protective layer W2.

The first protective layer W1 and the second protective layer W2 may be coupled to the display panel 10 through the adhesive layer PSA. The adhesive layer PSA may be a PSA film or an OCA layer. As described above, as the first protective layer W1 and the second protective layer W2 may include different materials from each other, the adhesive layer PSA under the first protective layer W1 and the second protective layer W2 may also include different materials as each other, but the disclosure is not limited thereto, and the adhesive layer PSA under the first protective layer W1 and the second protective layer W2 may include a same material as each other in another embodiment.

The first protective layer W1 and the second protective layer W2 are spaced apart from each other in the second folding area FA2, such that the adhesive layers PSA arranged on the bottom surfaces of the first protective layer W1 and the second protective layer W2 in the second folding area FA2 may also be spaced apart from each other.

In such an embodiment, as the adhesive layer PSA and the protective layer W1 and W2 are omitted on the display panel 10 overlapping the second folding area FA2, the display panel 10 may become vulnerable to moisture penetration or cracks. Thus, the cover layer CL covering the display panel 10 may be arranged on the display panel 10 overlapping the second folding area FA2. As the window protective layer WPL is omitted in the second folding area FA2, the cover layer CL may be exposed to outside.

In such an embodiment, a rib FR of a frame of the electronic device may be arranged or inserted in an area overlapping the cover layer CL in the second folding area FA2 to protect the cover layer CL.

In some embodiments, the electronic device may include the display device 1 and the frame accommodating the display device 1. The frame may include a main body arranged along an outer periphery of the display device 1 and the rib FR overlapping the second folding area FA2 and covering the display panel 10 and the cover layer CL. As a result, the stability of the electronic device may be improved by protecting the cover layer CL with the exposed rib FR.

In such an embodiment, a region of the display area DA of FIG. 1 that overlaps the second folding area FA2 may not display an image. Accordingly, in such an embodiment where the electronic device includes the rib FR that overlaps the second folding area FA2 and covers the display panel 10 and the cover layer CL, the stability of the electronic device may be improved without lowering the display performance of the electronic device.

In such an embodiment, as the region of the display area DA overlapping the second folding area FA2 may not display an image, although not shown in FIG. 7, the rib FR of the frame may also be arranged on the window protective layer WPL overlapping the second folding area FA2 of FIG. 7.

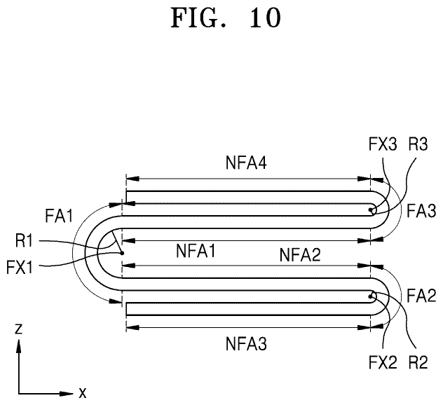

FIG. 10 is a cross-sectional view schematically showing an example of a folding shape of a display device according to another embodiment of the disclosure.

Referring to FIG. 10, a display device according to another embodiment of the disclosure may include a display panel including the first non-folding area NFA1, the second non-folding area NFA2, the third non-folding area NFA3, a fourth non-folding area NFA4, the first folding area FA1 between the first non-folding area NFA1 and the second non-folding area NFA2, the second folding area FA2 between the second non-folding area NFA2 and the third non-folding area NFA3, and a third folding area FA3 between the first non-folding area NFA1 and the fourth non-folding area NFA4.

As described above, the first non-folding area NFA1, the second non-folding area NFA2, and the first folding area FA1 of the display device 1, which are inner-folded, may include the main display on which the main screen is provided, and the out-folded third non-folding area NFA3 may include the sub-display on which the auxiliary screen of the display device 1) is provided.

The third folding area FA3 may be folded with respect to a third folding axis FX3 parallel to the second direction y. The first non-folding area NFA1 and the fourth non-folding area NFA4 may face each other, and the display device 1 may be out-folded such that a display surface is exposed to outside. The second folding area FA2 and the third folding area FA3 may be out-folded, and the first folding area FA1 may be inner-folded.

The fourth non-folding area NFA4 that is out-folded may include a second sub-display on which an auxiliary screen (e.g., a screen displaying specific notifications, state information, additional functions, etc.) supporting the main display of the display device 1 is displayed. In such an embodiment, as the rib FR)of the frame that accommodates the display device 1 is arranged in the out-folded third folding area FA3 like in the second folding area FA2, the screen of the display device 1 may not be driven in the third folding area FA3.

That is, the first non-folding area NFA1, the second non-folding area NFA2, and the first folding area FA1, which are inner-folded, may include the main display on which the main screen of the display device 1 is displayed (e.g., a screen on which main contents such as apps, moving images, games, etc., are displayed), and the third non-folding area NFA3 and the fourth non-folding area NFA4, which are out-folded, may include the sub-display and the second sub-display on which the auxiliary screen supporting the main display of the display device 1 is displayed (e.g., a screen on which specific notifications, state information, additional functions, etc. are displayed). As the rib FR of the frame that accommodates the display device 1 is arranged in the second folding area FA2 and the third folding area FA3 that are out-folded, the screen of the display device 1 may not be driven in the second folding area FA2 and the third folding area FA3.

A stacking structure of the display device 1 in the third folding area FA3 may be the same as a stacking structure of the display device 1 in the second folding area FA2. Thus, the first radius of curvature R1 in folding of the first folding area FA1 may be greater than a third radius of curvature R3 in folding of the third folding area FA3.

In some embodiments, the first radius of curvature R1 in folding of the first folding area FA1 may be in a range of about 1.3 mm to about 2.5 mm, the third radius of curvature R3 in folding of the third folding area FA3 may be in a range of about 0.2 mm to about 0.4 mm, and a ratio of the first radius of curvature R1 to the third radius of curvature R3 may be in a range of about 3.25 to about 12.5.

In such an embodiment, by omitting the bottom plate under the display panel in the third folding area FA3 and the fourth non-folding area NFA4 and omitting the protective layer and the adhesive layer in the third folding area FA3 to reduce the third radius of curvature R3 in the third folding area FA3, buckling may be effectively prevented in folding of the display device 1 and thus improving the stability of the display device 1 and the electronic device including the display device 1.

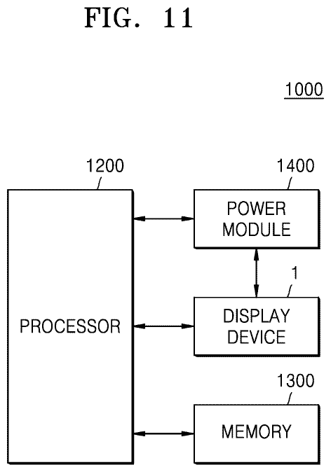

FIG. 11 is a block diagram of an electronic device according to an embodiment.

Referring to FIG. 11, an electronic device 1000 according to an embodiment may include the display device 1, a processor 1200, a memory 1300, and a power module 1400.

The display device 1 may receive data from the processor 1200 and provide visual information. The display device 1 may correspond to the display device 1 according to embodiments of the disclosure described above.

The processor 1200 may include at least one selected from a central processing unit (CPU), an application processor (AP), a graphic processing unit (GPU), a communication processor (CP), an image signal processor (ISP), and a controller. In an embodiment, for example, the processor 1200 may operate by executing at least one program.

The memory 1300 may store data information used for an operation of the processor 1200 or the display device 1. In an embodiment, for example, the memory 1300 may store at least one program. When the processor 1200 executes an application stored in the memory 1300, an image data signal and/or an input control signal may be transmitted to the display device 1 which may process the received signal and output image information through the display screen.

The power module 1400 may include a power supply module, such as a power adapter, a battery device, etc., and a power conversion module that converts power supplied by the power supply module to generate power used for the operation of the electronic device 1000. In an embodiment, for example, the power module 1400 may supply power to the display device 1.

At least one of components of the electronic device 1000 may be included in the display device 1 according to embodiments described above. Some of individual modules functionally included in a module may be included in the display device 1 and others may be provided separately from the display device 1.

The electronic device 1000 may further include the frame that accommodates the display device 1, as described above.

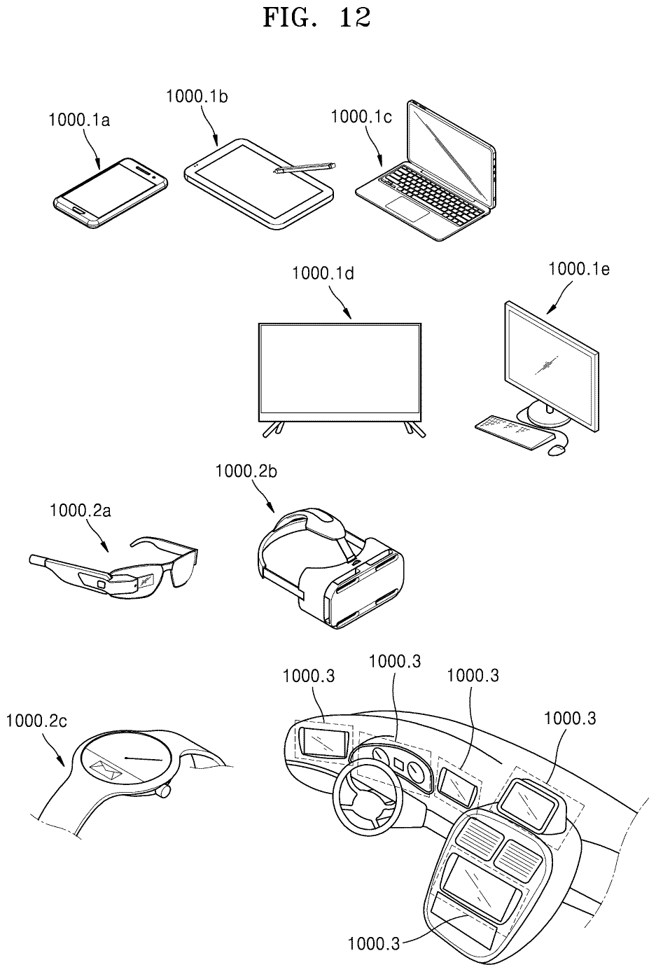

FIG. 12 show schematic diagrams of an electronic device according to various embodiments.

Referring to FIG. 12, various electronic devices to which the display device according to embodiments of the disclosure is applied may include not only image display electronic devices such as a smart phone 1000.1a, a tablet personal computer (PC) 1000.1b, a laptop computer 1000.1c, a television (TV) 1000.1d, a desk monitor 1000.1e, etc., but also wearable electronic devices including display devices such as smart glasses 1000.2a, a head mounted display 1000.2b, a smart watch 1000.2c, etc., and vehicle electronic devices 1000.3 including display devices such as an instrument panel, a center fascia, a center information display (CID) arranged on a dashboard, a room mirror display, etc., of vehicles.

According to embodiments of the disclosure, by omitting the bottom plate under the display panel in the second folding area and the third non-folding area, and omitting the protective layer and the adhesive layer in the second folding area, buckling may be effectively prevented in folding of the display device, thereby improving the stability of the display device and the electronic device including the display device.

However, effects that may be obtained through the disclosure are not limited to the above-described effects, and other technical effects not mentioned may be clearly understood by those of ordinary skill in the art from the description of the disclosure described below.

Each of the embodiments described above may be implemented independently, but it goes without saying that the structure of each embodiment may be applied in combination to other embodiments.

Although the disclosure has been described with reference to an example shown in the drawings, it will be understood by those of ordinary skill in the art that various modifications and equivalent other examples may be made from the shown example. Accordingly, the true technical scope of the disclosure should be defined by the technical spirit of the appended claims.

Specific implementations described in the embodiments are examples and do not limit the scope of the embodiments in any way. When there is no specific mentioning, such as “essential” or “important”, it may not be a necessary component for the application of the disclosure.

In the specification (especially, claims) of the disclosure, the use of the term “the” and similar indicators thereof may correspond to both the singular and the plural.

In addition, when the range is described in the embodiments, the range includes the disclosure to which an individual value falling within the range is applied (unless stated otherwise), and is the same as the description of an individual value constituting the range in the description of the disclosure.

Finally, when there is no apparent description of the order of operations constituting the method according to embodiments or a contrary description thereof, the operations may be performed in an appropriate order. However, the embodiments are not necessarily limited according to the describing order of the operations.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel comprising a first non-folding area, a second non-folding area, a third non-folding area, a first folding area between the first non-folding area and the second non-folding area, and a second folding area between the second non-folding area and the third non-folding area;
a bottom plate under the display panel to overlap the first non-folding area, the first folding area, and the second non-folding area; and
a protective layer on the display panel,
wherein the protective layer comprises a first protective layer overlapping the first non-folding area, the first folding area, and the second non-folding area, and a second protective layer overlapping the second folding area and the third non-folding area.

2. The display device of claim 1, wherein the first protective layer and the second protective layer comprise different materials from each other.

3. The display device of claim 1, wherein a first radius of curvature in folding of the first folding area is greater than a second radius of curvature in folding of the second folding area.

4. The display device of claim 3, wherein a ratio of the first radius of curvature to the second radius of curvature is in a range of about 3.25 to about 12.5.

5. The display device of claim 1, further comprising an adhesive layer between the display panel and the protective layer in an area overlapping the first non-folding area, the first folding area, the second non-folding area, and the third non-folding area.

6. The display device of claim 5, further comprising a cover layer covering the display panel in an area overlapping the second folding area.

7. The display device of claim 6, wherein a thickness of the adhesive layer is greater than a thickness of the cover layer.

8. The display device of claim 1, wherein in the second folding area, the first protective layer and the second protective layer are spaced apart from each other.

9. The display device of claim 1, further comprising a window protective layer covering the protective layer.

10. The display device of claim 1, wherein a thickness of the second protective layer is greater than a thickness of the first protective layer.

11. A display device comprising:
a display panel comprising a first non-folding area, a second non-folding area, a third non-folding area, a first folding area between the first non-folding area and the second non-folding area, and a second folding area between the second non-folding area and the third non-folding area;
a protective layer comprising a first protective layer overlapping the first non-folding area, the first folding area, and the second non-folding area, and a second protective layer overlapping the second folding area and the third non-folding area;
a window protective layer covering the first protective layer; and
a cover layer covering the display panel in an area overlapping the second folding area,
wherein the first protective layer and the second protective layer comprise different materials from each other.

12. The display device of claim 11, wherein the window protective layer extends from the second non-folding area to the third non-folding area to cover the second protective layer.

13. The display device of claim 11, wherein a first radius of curvature in folding of the first folding area is greater than a second radius of curvature in folding of the second folding area.

14. The display device of claim 13, wherein the second radius of curvature is a range of about 0.2 mm to about 0.4 mm.

15. The display device of claim 11, further comprising a bottom plate under the display panel and overlapping the first non-folding area, the first folding area, and the second non-folding area.

16. The display device of claim 11, further comprising a fourth non-folding area and a third folding area between the first non-folding area and the fourth non-folding area.

17. The display device of claim 16, wherein the first radius of curvature in folding of the first folding area is greater than a third radius of curvature in folding of the third folding area.

18. An electronic device comprising:
a memory which stores at least one program;
a processor which operates by executing the at least one program;
a display device which receives data from the processor and provides visual information; and
a power module which supplies power to the display device,
wherein the display device comprises:
a display panel comprising a first non-folding area, a second non-folding area, a third non-folding area, a first folding area between the first non-folding area and the second non-folding area, and a second folding area between the second non-folding area and the third non-folding area;
a bottom plate under the display panel to overlap the first non-folding area, the first folding area, and the second non-folding area; and
a protective layer on the display panel,
wherein the protective layer comprises a first protective layer overlapping the first non-folding area, the first folding area, and the second non-folding area, and a second protective layer overlapping the second folding area and the third non-folding area.

19. The electronic device of claim 18, further comprising a frame which accommodates the display device,
wherein the frame overlaps the second folding area and comprises a rib covering the display panel.

20. The electronic device of claim 19, further comprising a cover layer between the rib and the display panel.
